(19) United States
(12) Patent Application Publication
(10) Pub. No.: US 2021/0195781 A1
(43) Pub. Date: Jun. 24, 2021

(54) MOVABLE LOCKS WITH CARD RETAINERS

(71) Applicant: Hewlett-Packard Development Company, L.P., Spring, TX (US)

(72) Inventors: Hai-Lung Hung, Taipei City (TW); Cheng-Yi Yang, Taipei City (TW); Szu Tao Tong, Taipei City (TW)

(73) Assignee: Hewlett-Packard Development Company, L.P., Spring, TX (US)

(21) Appl. No.: 17/054,644

(22) PCT Filed: Sep. 12, 2018
(86) PCT No.: PCT/US2018/050729

§ 371 Date: Nov. 11, 2020

(51) Int. Cl. H05K 7/14

(52) U.S. Cl. CPC H05K 7/142; H05K 7/1408

(57) ABSTRACT

In an example, a movable lock may include a lock bar and a pivot disposed at a first end of the lock bar. The movable lock may also include a card retainer disposed on the lock bar at a second end of the lock bar, opposite the first end. The card retainer may include a card notch sized to receive an edge of a system card.

### BACKGROUND

Electronic devices, including computing devices, may include expansion cards, system cards, or other components which may provide additional or enhanced functionality to the electronic device. Such components may be engaged with or installed into the electronic device through the use of expansion slots or other connectors. Such slots or connectors may sometimes be disposed within the electronic device and/or be attached to a system board of the electronic device.

### BRIEF DESCRIPTION OF THE DRAWINGS

FIG. 1 is a perspective view of an example movable lock with a card retainer.

FIG. 2A is a perspective view of another example movable lock with a card retainer.

FIG. 2B is a side view of the example movable lock of FIG. 2A.

FIG. 3A is a perspective view of another example movable lock with a card retainer.

FIG. 3B is a perspective exploded view of the example movable lock of FIG. 3A.

FIG. 4A is a perspective view of an example system board assembly having an example movable lock with a card retainer.

FIG. 4B is a top view of the example system board assembly of FIG. 4A.

FIG. 4C is a top view of the example system board assembly of FIG. 4A.

FIG. 4D is a perspective view of the example system board assembly of FIG. 4A.

FIG. 5 is top view of another example system board assembly having an example movable lock with a card retainer.

FIG. 6A is perspective view of an example electronic device having an example movable lock with a card retainer.

FIG. 6B is another perspective view of the example electronic device of FIG. 6A.

FIG. 6C is another perspective view of the example electronic device of FIG. 6A.

### DETAILED DESCRIPTION

Electronic devices, including computing devices, may include expansion cards, system cards, or other components which may provide additional or enhanced functionality to the electronic device. In some situations, such components may be used to supplement existing components of the device, e.g., increase the storage capacity of the electronic device. Such components may be engaged with or installed into the electronic device through the use of expansion slots or other connectors. Such slots or connectors may sometimes be disposed within the electronic device and/or be attached to a motherboard, a riser card, or other type of system board of the electronic device. Such components may have an edge connector having pins such that, upon the edge connector, and thus the component itself, being engaged with a connector or slot of the electronic device, the pins on the edge connector may be engaged with complementary pins in the slot or connector, thereby enabling electronic communication between the system board and the system card or component.

In some situations, the edge connector of the system card or component may be disposed on a single edge, or portion thereof of the component. Thus, upon installation, the system card or component may only be constrained by the engagement of the edge connector with the slot or connector of the system board, thereby leaving the other edges of the system card free or cantilevered from the system board. This may create an insecure attachment of the system card to the system board, wherein the system card may wobble, vibrate, or otherwise move or loosen from the connector or slot.

In some situations, a free end, i.e., and end of the system card not engaged with the connector or slot, may be fixed or constrained to the system board or another component of the electronic device by a fastener so as to provide a more secure attachment of the system card to the device. Such fasteners may directly or indirectly secure the free end of the system card to an aperture or other fastening or attachment feature of the system board or other component. However, in some situations it may be desirable to be able to fix or securely attach different system cards having differing sizes and/or lengths to the system board. Such differently-sized system cards may each engage with the same slot or connector of the electronic device, but the free end of each system card may reside in a different location, e.g., relative to the system board to which the system card is attached. Therefore, in order for a system board of an electronic device to be able to receive and accommodate system cards having different sizes in a secure fashion, the system board may need to have multiple fastening or attachment features in different locations, each corresponding to a possible size of a system card to be used.

In some situations, when installing a system card to a system board of an electronic device, regardless of the size of the card, it may be difficult to handle, attach, and/or install the fastener for the free end of the card to the corresponding attachment feature. This may be due to the small size of the fastener, the attachment feature and or connector or slot being in a hard-to-reach location, or the location being hard to access with a fastening tool. Such difficulty may result in the fastener being dropped and/lost during the installation process. Therefore, it may be desirable for an electronic device, or a system board thereof, to have a simple way of securely fastening a system card or supplemental component to the system board that may minimize difficulty and the potential for lost components. It may be further desirable to have a way of securely fastening system cards with different lengths or sizes to a system board.

Implementations of the present disclosure provide an apparatus that may securely attach a system card or other supplemental component to an electronic device, or a system board thereof. Further, examples described herein may be able to securely attach differently-sized system cards or components and may also be implemented so as to make the installation process easier and/or minimize the possibility of lost components.

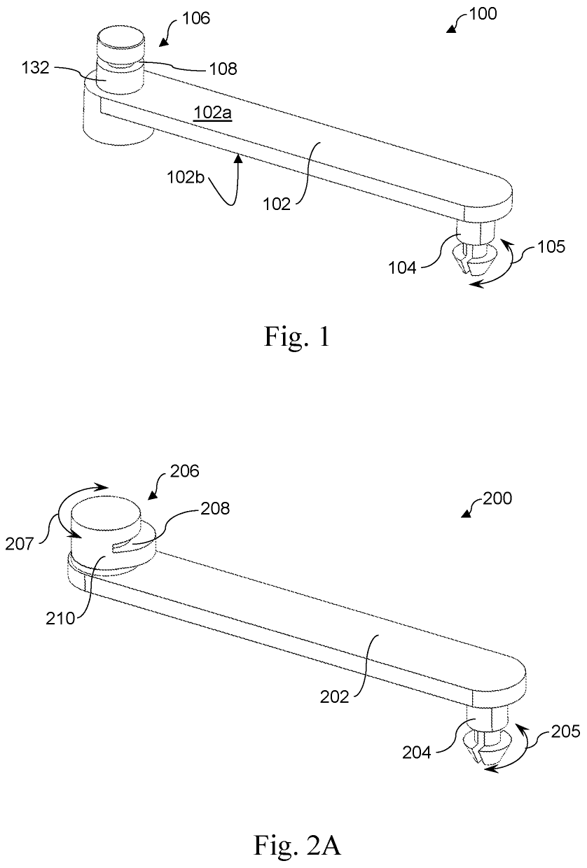

Referring now to FIG. 1, a perspective view of an example movable lock 100 having a card retainer 106 is illustrated. The movable lock 100 may further include a lock bar 102, and a pivot 104 disposed at a first end of the lock bar 102. The card retainer 106 may be disposed on the lock bar 102 at a second end of the lock bar 102, opposite the first end. The card retainer 106 may include a card notch 108 sized to receive an edge of a system card. The pivot 104 may be a post, tab, or other protrusion extending from a bottom surface 102b of the lock bar 102. In some implementations, the pivot 104 may enable the movable lock 100 to rotate or pivot, e.g., along direction 105, relative to a component to which the movable lock 100 may be attached. In some implementations, the pivot 104 may be fixed to the lock bar 102 and may be movably engaged with the component, and in other implementations, the pivot 104 may be movably attached to the lock bar 102 and may be fixed to the component to enable such rotation of the movable lock 100.

In some implementations, the card retainer 106 may include a boss 132 extending from a top surface 102a of the lock bar 102. The top surface may be opposite from the bottom surface 102b. The boss 132 may define a bottom portion of the card notch 108, while the card retainer 106 may include another post, tab, or other protrusion defining a top portion of the card notch 108.

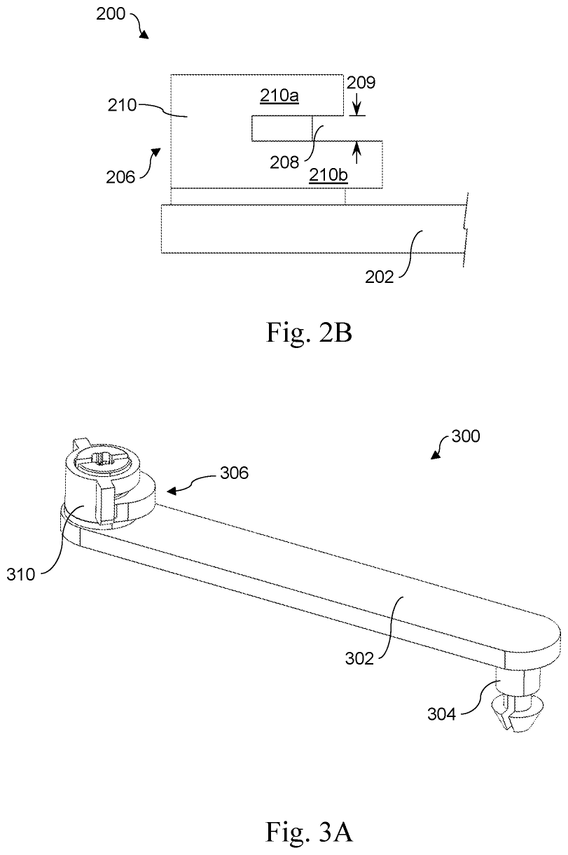

Referring now to FIGS. 2A-2B, perspective and side views of another example movable lock 200 having a card retainer 206 are illustrated. Example movable lock 200 and card retainer 206 may be similar to example movable lock 100 and card retainer 106, described above. Further, the similarly-named elements of example movable lock 200 and card retainer 206 may be similar in function and/or structure to the respective elements of example movable lock 100 and card retainer 106, as they are described above. Movable lock 200 may include a lock bar 202 and a pivot 204, which may enable the movable lock 200 to rotate or pivot along example direction 205, relative to a component to which the movable lock 200 is attached.

In some implementations, card retainer 206 may include a retainer nut 210. Retainer nut 210 may be rotatably disposed on a top surface of the lock bar 202 so as to rotate relative to the lock bar 202, e.g., along direction 207. The retainer but 210 may include and/or define a card notch 208. The card notch 208 may include a height, size, and/or other structure suitable to receive and engage with an edge of a system card. For example, card notch 208 may have a height 209, which may be large enough to receive an edge of a system card within the card notch 208. In some implementations, retainer nut 210 may include a top portion 210a, and a bottom portion 210b, spaced from the top portion 210a. The spacing between top and bottom portions 210a and 210b may define the card notch 208. In some implementations, the bottom portion 210b may extend radially from the retainer nut 210 further than the top portion 210a, thus defining a shelf or ledge upon which an edge of a system card may be disposed or supported.

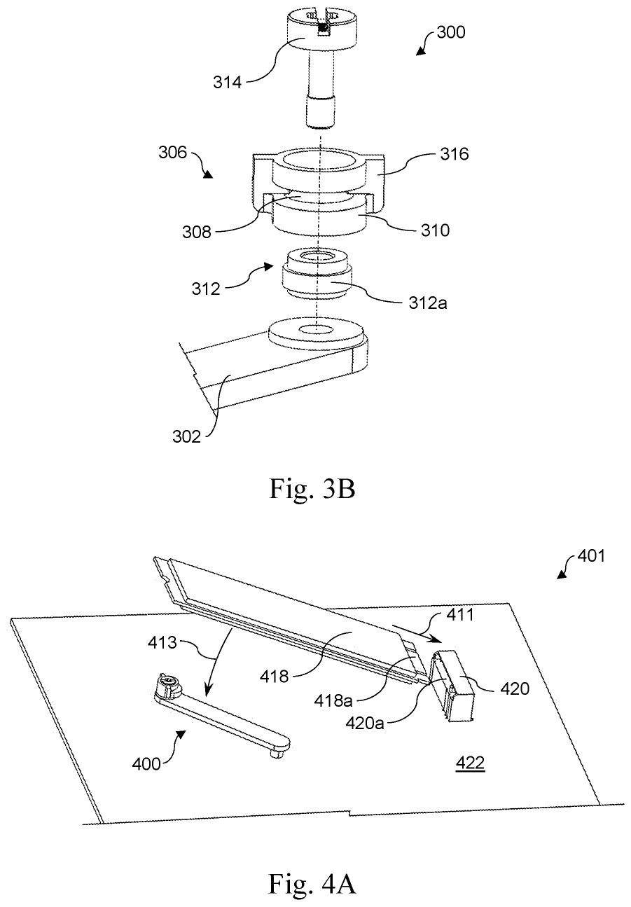

Referring now to FIG. 3A a perspective view of another example movable lock 300 having a card retainer 306 is illustrated. Example movable lock 300 and card retainer 306 may be similar to other example movable locks and card retainers, described above. Further, the similarly-named elements of example movable lock 300 and card retainer 306 may be similar in function and/or structure to the respective elements of other example movable locks and card retainers, as they are described above. Referring additionally to FIG. 3B, an exploded perspective view of example movable lock 300 is illustrated. Movable lock 300 may include a lock bar 302 and a pivot 304. Additionally, the card retainer 306 may include a retainer nut 310. In some examples, the retainer nut 310 may include a substantially rounded or cylindrical shape. In further implementations, the retainer nut 310 may include a tubular or hollow shape, having an inner bore. In further implementations, the retainer nut 310 may define a card notch 308, which may be a window, opening, or cutout extending radially from an outer surface of the retainer nut 301 to the inner bore. The card notch 308 may be sized and structured so as to receive and engage with an edge of a system card. In some implementations, the retainer nut 310 may include a pair of tabs 316 extending radially from the retainer nut 310, adjacent the card notch 308. In some examples, the tabs 316 may be disposed opposite one another. In other examples, the retainer nut 310 may include a single tab 316 extending radially from the retainer nut 310. The tabs 316 may be oriented relative to the card notch 308 such that, if the card notch 308 is engaged with an edge of a system card, the tabs 316 may abut against the edge of the system card so as to add stability and security to the engagement.

In some examples, the card retainer 306 may further include a support sleeve 312, which may be disposed within the retainer nut 310, or the inner bore thereof. The support sleeve 312 may include a curved or rounded outer surface 312a such that, when the support sleeve 312 is assembled or disposed within the retainer nut, the outer surface 312a of the support sleeve 312 is disposed adjacent to, at the rear of, or within the card notch 308. Thus, when the card notch 308 is engaged with an edge of a system card, the outer surface 312a of the support sleeve 312 may engage and support a rounded opening on the edge of the system card.

In some implementations, the card retainer 306 may further include a fastener 314. The fastener 314 may be a screw, bolt, pin, or other mechanical fastener that may attach the retainer nut 310 to the lock bar 302. In some implementations, the fastener 314 may extend through the retainer nut 310, the support sleeve 312, and the lock bar 302. In other implementations, the fastener 314 may additionally extend through the lock bar 302 so as to protrude from a bottom surface of the lock bar 302. The fastener 314 may thus engage with an attachment feature disposed beneath the movable lock 300 and/or the lock bar 302. In some implementations, the attachment feature may be on a system board and the fastener 314 may fix the lock bar 302 in position relative to the system board.

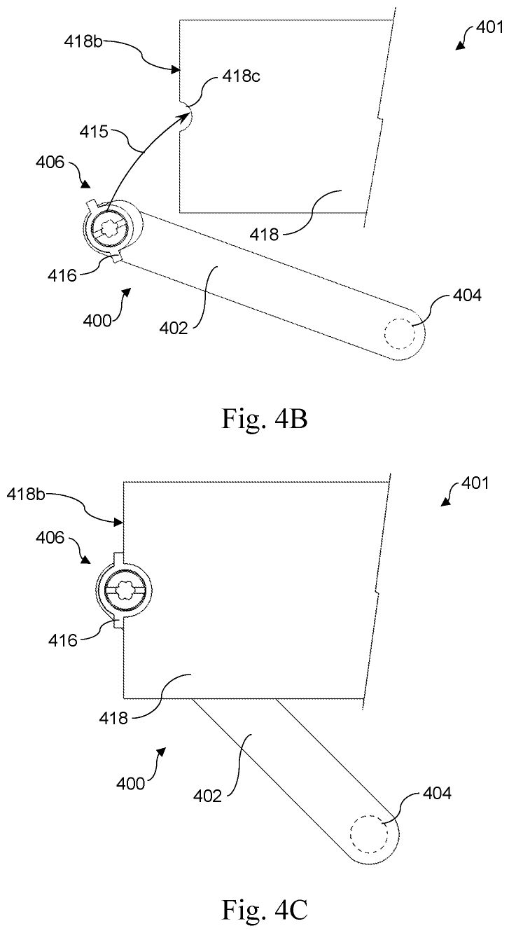

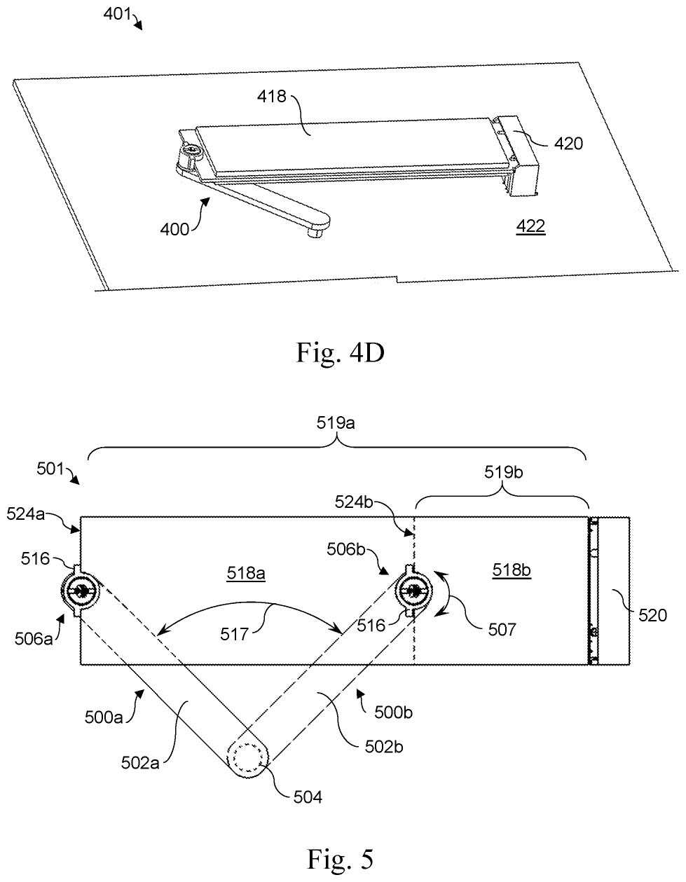

Referring now to FIG. 4A, a perspective view of an example system board assembly 401 is illustrated. The example system board assembly 401 may have an example movable lock 400 with a card retainer 406. Example movable lock 400 and card retainer 406 may be similar to other example movable locks and card retainers, described above. Further, the similarly-named elements of example movable lock 400 and card retainer 406 may be similar in function and/or structure to the respective elements of other example movable locks and card retainers, as they are described above.

System board assembly 401 may include a system board 422. System board 422 may be a part or component of an electronic device, in some examples. In further implementations, the system board 422 may mechanically and electrically support other components of an electronic device, including, but not limited to, processors, memory, system cards, resistors, capacitors, and/or other types of components. In some implementations, system board 422 may be include conductive traces or pathways etched into the board. Further, the system board 422 may be made of silicon and the conductive traces may be copper. In some implementations, the system board may be a printed circuit board/assembly (PCB/PCA), and in further implementations, the system board 422 may be a motherboard, daughterboard, expansion card, or other type of circuit board.

In some examples, the system board assembly 401 and/or the system board 422 thereof, may include a card connector 420 attached to the system board 422. The card connector 420 may be a component suitable to operably engage, i.e., mechanically and electrically, a system card, accessory card, expansion card, or other component, with the system board 422. In some examples, the card connector 420 may have an opening 420a to receive and engage with an edge, or edge connector, of a system card. The system board 422 may include an attachment feature or plurality of attachment features, in some implementations. Each of the attachment features may be aligned with the opening 420a of the card connector 420. System board assembly 401 may further include a system card 418. FIG. 4A illustrates system card 418, or a first end 418a thereof, as being inserted into the card connector 420, or, more specifically, the opening 420a thereof. System card 418 may be inserted into the card connector 420 along example direction 411, in some examples, and may be swung or rotated downwards toward the system board 422, e.g., along direction 413, to fully engage the system card 418 with the card connector 420. In some implementations, the first end 418a of the system card 418 may include an edge connector comprising pins. The pins may electrically and mechanically engage with the opening 420a of the card connector 420 so as to enable electronic communication between the system card 418 and the system board 422. Once the first end 418a of the system card 418, or the edge connector thereof, is engaged with the card connector 420, a second end, or free end, i.e., an end or edge of the system card 418 not engaged with the card connector 420, may be aligned with one of the attachment features of the system board 422. In some implementations, the system card 418 may enhance or provide additional functionality to the system board assembly. In further implementations, the system card 418 may be or may include a storage drive, processor, or other component. In yet further implementations, the system card 418 may be a memory stick or card. In yet even further implementations, the system card 418 may be a M.2 specification expansion card.

Referring now to FIGS. 4B-4C, top views of the example system board assembly 401 are illustrated. For clarity, only the movable lock 400 and part of the system card 418 are illustrated in these figures. FIG. 4B illustrates the system card 418 as being fully engaged with the card connector 420 at the first end, and having the second end, or free end, be cantilevered from the card connector 420. Thus, the free end or second end is not secured to the system board 422, and therefore poses the risk of moving or vibrating out of place inadvertently. In order to avoid such a situation, the movable lock 400 may be employed to secure the second end of the system card 418.

The movable lock 400 may include a lock bar 402, a pivot 404, and a card retainer 406. The pivot 404 may be directly rotatably or pivotably attached to the system board 422, or an intermediary component (providing an indirect attachment to the system board 422), such that the movable lock 400 may be able to pivot or rotate relative to the system board 422, and thus the system card 418. Once the system card 418 is engaged with the card connector 420, the movable lock 400 may be pivoted, e.g., along direction 415, relative to the system card 418 and system board 422, about the pivot 404, so as to engage the card retainer 406 with an edge 418b of the second end of the system card 418. FIG. 4C illustrates the card retainer 406, and thus the movable lock 400, as being engaged with the system card 418. The card retainer 406 may have a card notch that is sized to receive and engage with the edge 418b. Additionally, in some examples, the card notch may have a rounded surface within the notch to engage with a rounded opening 418c or cutout on the edge 418b of the second end of the system card 418. Yet further, in some examples, the card retainer may have a retainer nut with tabs 416. Upon the card retainer 406 becoming engaged with the edge 418b, the tabs 416 may abut against the edge 418b, thereby providing a stable and secure engagement between the second end of the system card 418 and the card retainer 406. The engagement of the card retainer 406 with the system card 418 may enable the movable lock 400 to provide a secure installation to the system card 418 within the system board assembly 401. Referring now to FIG. 4D, a perspective view of the system board assembly 401 is illustrated wherein the movable lock 400 is securing the system card 418 in place.

Referring now to FIG. 5, a top view of another example system board assembly 501 having an example movable lock 500 with a card retainer 506 is illustrated. Example movable lock 500 and card retainer 506 may be similar to other example movable locks and card retainers, described above. Further, the similarly-named elements of example movable lock 500 and card retainer 506 may be similar in function and/or structure to the respective elements of other example movable locks and card retainers, as they are described above. FIG. 5 illustrates the movable lock 500 of system board assembly 501 as being in two possible configurations, which are represented by movable lock 500a and movable lock 500b. Further, system board assembly 501 illustrates a card connector 520 as being operably engaged with each of two different system cards 518, represented as first system card 518a, having a first length 519a, and second system card 518b, having a second length 519b. Second length 519b is shorter than first length 519a. Since system cards may come in a variety of sizes and/or lengths, it is desirable that movable lock 500 be able to secure system cards of different lengths. Thus, movable lock 500 may be pivotable or rotatable about pivot 504 relative to the system board and system card, e.g., along pivot direction 517.

When using the first system card 518a with first length 519a, movable lock 500a may be in a first position relative to the card connector 520 and system board. When disposed in the first position, the card retainer 506a of the movable lock 500a may engage with an edge 524a of a second end or free end of system card 518a in order to secure the system card 518a. When engaged with the edge 524a, tabs 516 on the card retainer 506a, or a retainer nut thereof, may be oriented so as to be substantially parallel to and abut against edge 524a.

When using the second system card 518b with second length 519b, movable lock 500b may be in a second position relative to the card connector 520 and system board. I.e., movable lock 500 may be movable along pivot direction 517 so as to be aligned with an edge of the system card 518 that is being utilized. When disposed in the second position, the card retainer 506b of the movable lock 500b may engage with an edge 524b, illustrated in phantom, of a second end or free end of system card 518b in order to secure the system card 518b. When engaged with the edge 524b, tabs 516 on the card retainer 506b, or a retainer nut thereof, may be oriented so as to be substantially parallel to and abut against edge 524b. It should be noted that card retainer 506, or a retainer nut thereof, is pivotable relative to the lock bar 502 so as to be able to align the tabs 516 with the edge of the system card 518 in use. Stated differently, when using a system card of a first length 519a, the card retainer 506a will have a first orientation relative to the lock bar 502a. When adapting the movable lock 500b for use with a system card of a second length 519b, the card retainer 506b will have a second orientation, e.g., adjusted along direction 507, relative to the lock bar 502b so as to align the tabs 516 for engagement with the edge of the system card. Further, while FIG. 5 illustrates two potential positions of the movable lock so as to be able to secure two different length system cards, it is contemplated that any number of different length system cards could be accommodated. For example, the lock bar 502 could employ a level of adjustability in length, e.g., through a telescoping or other adjustable action, so as to adapt the movable lock 500 to be able to secure a system card having a length other than as illustrated.

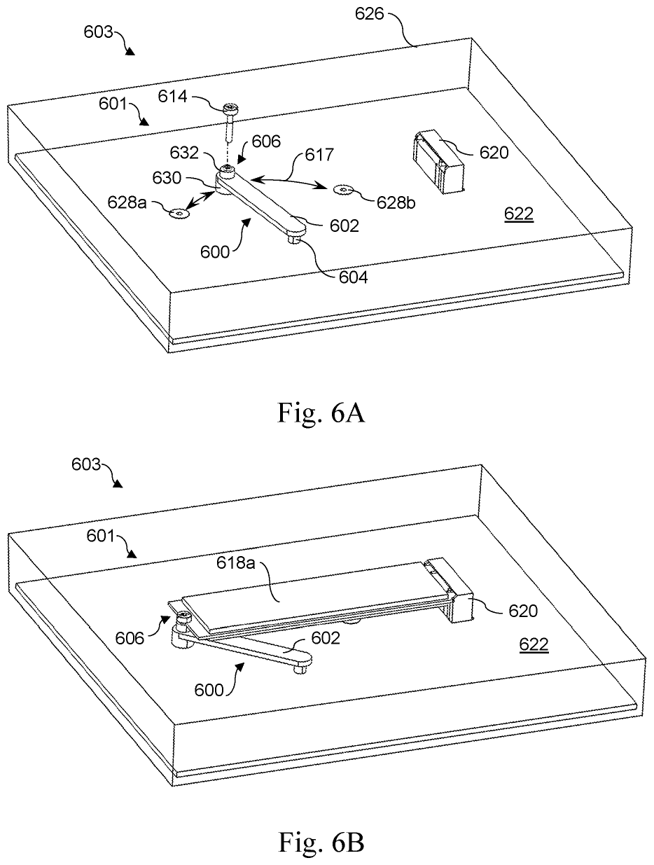

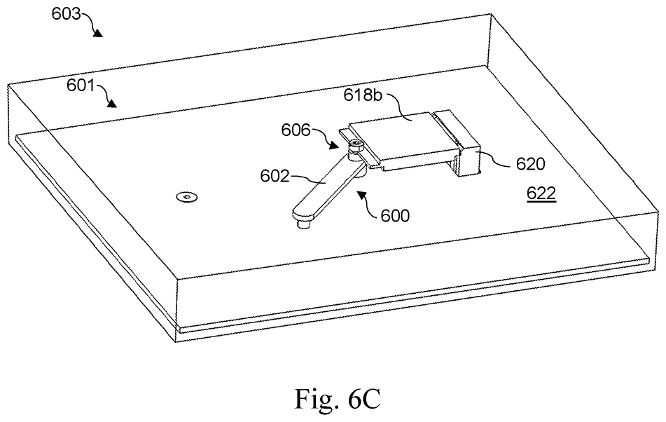

Referring now to FIG. 6A, a perspective view of an example electronic device 603 having an example system board assembly 601 is illustrated. System board assembly 601 may include an example movable lock 600 with card retainer 606. Example movable lock 600 and card retainer 606 may be similar to other example movable locks and card retainers, described above. Further, the similarly-named elements of example movable lock 600 and card retainer 606 may be similar in function and/or structure to the respective elements of other example movable locks and card retainers, as they are described above.

Electronic device 603 may include a chassis 626, with system board assembly 601 being disposed, at least partially, within the chassis 626. For the sake of clarity, the chassis 626 is illustrated as being transparent in FIG. 6A-6C so as to clearly illustrate the system board assembly 601 within. The electronic device 603, in some examples, may be a computing device such as a personal computer (PC), a notebook computer or laptop, a tablet, smartphone, mini-PC, computer tower, or other type of computing device. In other implementations, the electronic device 603 may be an imaging device such as a printer, scanner, copier, multi-function imaging device, additive manufacturing device (3D printer), or other type of imaging device. In yet other examples, the electronic device 603 may be any device that may have a system card installed within. The chassis 626 may be or may be a portion of a housing, frame, case, enclosure or other structural or aesthetic component of the electronic device 603.

The system board assembly 601 may include a system board 622, and a card connector 620 attached to the system board 622. In some implementations, the system board 622 may include an attachment feature or a plurality of attachment features. In some examples, the system board 622 may include two attachment features: a first attachment feature 628a and a second attachment feature 628b. Each of the attachment features (referred to collectively as attachment features 628) may be aligned with an opening of the card connector 620. The attachment features 628 may be aligned as an array in series with the opening of the card connector 620 such that a second or free end of a system card engaged with the card connector may be aligned with one of the attachment features 628, despite the fact that the card connector 620 may accept system cards of differing lengths. In some examples, each attachment feature 628 may include an attachment boss extending from the system board 622 and an attachment aperture extending at least partially through the attachment boss. In some implementations, the attachment boss may extend from the side of the system board 622 on which the card connector 620 and the movable lock 600 is disposed (a top side), and in other implementations, the attachment boss may extend from the opposite side of the system board 622 (a bottom side).

In the illustrated example, movable lock 600 may have a lock bar 602, a pivot 604, and a card retainer 606. FIG. 6A illustrates movable lock 600 as being rotatably attached to the system board 622, and movable between alignment with first attachment feature 628a and alignment with second attachment feature 628b, e.g., along pivot directions 617. In other words, the movable lock 600 is pivotable relative to the system board 622 such that the card retainer 606 may be aligned with either of the two attachment features 628. Depending on the size of the system card to be used with the electronic device, the movable lock 600 may be moved to one position or the other. Card retainer 606 may include a boss extending from a top surface of the lock bar 602, an aperture extending through the boss 632 and the lock bar 602, and a fastener 614. When assembled, the fastener 614 may be spaced from a top surface of the boss so as to define a card notch. The fastener 614 may extend through the boss 632 and the lock bar 602 and into the attachment boss of one of the attachment features to fix the movable lock 600 in place relative to the system board 622. In examples wherein the attachment bosses extend from the bottom side of the system board, the movable lock 600 may further have a support boss 630 extending from a bottom side of the lock bar 602 to provide support to the movable lock 600 between the lock bar 602 and the system board 622.

Referring additionally to FIG. 6B, another perspective view of example electronic device 603 is illustrated, wherein a system card 618a of a first length is engaged with the card connector 620. In the illustrated example, the system card 618a extends away from the card connector 620 such that a second end or free end, or an edge thereof, of the system card 618a is aligned with one of the attachment features 628. Specifically, system card 618a has a first length such that the second end is aligned with attachment feature 628a. As such, movable lock 600 can be pivoted about the pivot 604 so as to align the card retainer 606 with attachment feature 628a. At this point, the card retainer 606 is also aligned with the edge of the second end of system card 618a, and the card retainer 606, or the card notch thereof, can engage with the edge of the second end. In some examples, in order to secure the system card 618a to the system board 622, the edge of the second end, or a rounded opening thereof, can be abutted against the shank of the fastener 614, and the fastener 614 can then be tightened so as to clamp or pinch the second end of the system card 618a, as well as tighten the card retainer 606 to the attachment feature 628a of the system board 622. In other words, tightening the fastener 614 not only secures the card retainer 606 to the second end of the system card 618a, but also fixes the movable lock 600 in place relative to the system board 622 by engaging with the attachment boss and attachment aperture of the attachment feature 628a.

Referring now to FIG. 6C, another perspective view of electronic device 603 is illustrated, where a system card 618b of a second length, different than the first length of system card 618a, is engaged with the card connector 620. Similar to described above regarding securing the system card 618a, the system card 618b extends from the card connector 620 such that the second end or free end, or an edge thereof, of the system card 618b is aligned with one of the attachment features 628. Specifically, in the illustrated example, the system card 618b has a second length such that the second end is aligned with attachment feature 628b. As such, movable lock 600 can be pivoted about the pivot 604 so as to align the card retainer 606 with attachment feature 628b. Similar to FIG. 6B, the fastener 614 can be tightened so as to both securely hold the system card 618b, as well as to fix the movable lock 600 relative to the system board 622. Thus, the movable lock 600 can provide a simple way to securely fix a system card in place on a system board, while still being able to accommodate system cards of differing sizes.

What is claimed is:

1. A movable lock, comprising:
a lock bar;
a pivot disposed at a first end of the lock bar; and
a card retainer disposed on the lock bar at a second end of the lock bar, opposite the first end, comprising a card notch sized to receive an edge of a system card.

2. The movable lock of claim 1, wherein the card retainer comprises a retainer nut rotatably disposed on a top surface of the lock bar so as to rotate relative to the lock bar, the retainer nut defining the card notch.

3. The movable lock of claim 2, wherein the retainer nut comprises a pair of tabs extending radially from the retainer nut adjacent the card notch, the tabs to abut against the edge of the system card if the system card is engaged with the card notch.

4. The movable lock of claim 2, wherein the card retainer further comprises a support sleeve disposed within the retainer nut and a fastener to attach the retainer nut to the lock bar.

5. The movable lock of claim 4, wherein the support sleeve has a curved outer surface within the card notch to engage with a rounded opening on the edge of the system card if the system card is engaged with the card notch.

6. The movable lock of claim 4, wherein the fastener is to extend through the retainer nut, the support sleeve and the lock bar so as to protrude from a bottom surface of the lock bar, the fastener to engage with an attachment feature beneath the lock bar on a system board to fix the lock bar in position relative to the system board.

7. The movable lock of claim 1, wherein the card retainer comprises a boss extending from a top surface of the lock bar, an aperture extending through the boss and the lock bar, and a fastener engaged with the aperture, the fastener spaced from a top surface of the boss so as to define the card notch.

8. A system board assembly, comprising:
a system board;
a card connector attached to the system board, the system board comprising two attachment features aligned with an opening of the card connector;
a system card engaged with the opening of the card connector at a first end of the system card, a second end of the system card aligned with one of the two attachment features; and
a movable lock, comprising:
a lock bar;
a pivot disposed at a first end of the lock bar pivotably attached to the system board; and
a card retainer disposed on the lock bar at a second end of the lock bar, opposite the first end, comprising a card notch sized to receive an edge of the second end of the system card.

9. The system board assembly of claim 8, wherein each of the attachment features comprises an attachment boss extending from the system board and an attachment aperture extending at least partially through the attachment boss.

10. The system board assembly of claim 9, wherein the card retainer comprises a boss extending from a top surface of the lock bar, an aperture extending through the boss and the lock bar, and a fastener spaced from a top surface of the boss so as to define the card notch, wherein the fastener is to extend through the boss and into the attachment boss of one of the attachment features to fix the movable lock in place relative to the system board.

11. The system board assembly of claim 9, wherein the card retainer comprises a retainer nut rotatably disposed on a top surface of the lock bar so as to rotate relative to the lock bar, the retainer nut defining the card notch.

12. The system board assembly of claim 11, wherein the card retainer further comprises a fastener extending through the retainer nut and into the attachment boss of one of the attachment features to fix the movable lock in place relative to the system board.

13. An electronic device, comprising:
a chassis; and
a system board assembly disposed within the chassis and comprising:
a system board;
a card connector attached to the system board, the system board comprising two attachment features aligned with an opening of the card connector;
a system card engaged with the opening of the card connector at a first end of the system card, a second end of the system card aligned with one of the two attachment features; and
a movable lock, comprising:
a lock bar;
a pivot disposed at a first end of the lock bar pivotably attached to the system board; and
a card retainer disposed on the lock bar at a second end of the lock bar, opposite the first end, comprising a card notch sized to receive an edge of the second end of the system card.

14. The electronic device of claim 13, the movable lock is pivotable relative to the system board such that the card retainer may be aligned with either of the two attachment features.

15. The electronic device of claim 14, wherein the card retainer comprises a boss extending from a top surface of the lock bar, an aperture extending through the boss and the lock bar, and a fastener spaced from a top surface of the boss so as to define the card notch, wherein the fastener is to extend through the boss and into one of the attachment features to fix the movable lock in place relative to the system board.
